(19) United States
(12) Patent Application Publication
(10) Pub. No.: US 2024/0321996 A1
(43) Pub. Date: Sep. 26, 2024

(54) SEMICONDUCTOR DEVICE AND METHOD OF MANUFACTURING SEMICONDUCTOR DEVICE

(71) Applicant: LAPIS Semiconductor Co., Ltd., Yokohama (JP)

(72) Inventor: Shouhei HIEJIMA, Yokohama (JP)

(73) Assignee: LAPIS Semiconductor Co., Ltd., Yokohama (JP)

(21) Appl. No.: 18/604,464

(22) Filed: Mar. 13, 2024

(30) Foreign Application Priority Data
Mar. 22, 2023 (JP) 2023-045929

(51) Int. Cl. H01L 29/49; H01L 23/29; H01L 23/31

(52) U.S. Cl. CPC H01L 29/4908; H01L 23/293; H01L 23/3135

(57) ABSTRACT

A semiconductor device includes a thin-film metal electrode provided on a first main surface of a support base, a thin-film resin layer covering an edge of the thin-film metal electrode, a thick-film metal body located above the thin-film metal electrode and containing copper, a thick-film resin body covering a lateral surface of the thick-film metal body, and a structure body including at least one of a first film provided on the first main surface and a second film provided on a second main surface. The thick-film metal body, the thin-film metal electrode, and the support base are arranged along a direction of a first axis. Upper surfaces of the thick-film metal body and the thick-film resin body extend along a reference plane intersecting with the first axis. A thermal expansion coefficient of the first film is between those of the thick-film resin body and a semiconductor of the support base.

### CROSS-REFERENCE TO RELATED APPLICATION

This application claims the priority benefit of Japan application serial no. 2023-045929, filed on Mar. 22, 2023. The entirety of the above-mentioned patent application is hereby incorporated by reference herein and made a part of this specification.

### BACKGROUND

### Technical Field

The disclosure relates to a semiconductor device and a method of manufacturing a semiconductor device.

### Related Art

Patent Document 1 (Japanese Patent Application Laid-Open No. 2016-146395) discloses minimizing bending of semiconductor devices obtained by dividing a wafer. This manufacturing method includes a first adhering process, a thinning process, a dividing process, a second adhering process, and a peeling process. In the first adhering process, a support plate is adhered to a first main surface of a wafer formed with an integrated circuit on the first main surface. In the thinning process, after the first adhering process, the wafer is thinned by performing polishing or grinding on a second main surface of the wafer. In the dividing process, at the same time as or after the thinning process, the wafer is divided into a plurality of chip body parts. In the second adhering process, after the dividing process, a plurality of reinforcing layers are respectively adhered to the second main surfaces of the plurality of chip body parts 10. In the peeling process, the support plate is peeled off after the second adhering process.

In the manufacturing method of a semiconductor device for a chip size package (or chip scale package, CSP) structure, warpage of the wafer during the manufacturing process may become an obstacle in various processes.

In conventional CSP structures, effort has been directed to reducing warpage of large semiconductor chips. However, warpage is associated not only with the size of the semiconductor chip but also with the size of an electrode related to the CSP structure in the semiconductor chip.

### SUMMARY

A semiconductor device according to a first aspect of the disclosure includes a support base, at least one thin-film metal electrode, a thin-film resin layer, at least one thick-film metal body, a thick-film resin body, and a structure body. The support base includes a first main surface and a second main surface on an opposite side of the first main surface, and includes a semiconductor. The at least one thin-film metal electrode is provided on the first main surface of the support base. The thin-film resin layer includes a first opening on the thin-film metal electrode and covers an edge of the thin-film metal electrode. The at least one thick-film metal body is located above the thin-film metal electrode and the thin-film resin layer and includes a metal film containing copper. The thick-film resin body covers a lateral surface of the thick-film metal body and is provided on the first main surface of the support base. The structure body includes at least one of a first film provided on at least a portion of the first main surface of the support base and a second film provided on at least a portion of the second main surface of the support base. The first film is provided between the thin-film resin layer and the thick-film resin body, and the support base is provided between the second film and the thick-film resin body. The thick-film metal body, the thin-film metal electrode, and the support base are arranged along a direction of a first axis. An upper surface of the thick-film metal body and an upper surface of the thick-film resin body extend along a reference plane intersecting with the first axis. A thickness of the thick-film metal body is larger than a thickness of the thin-film metal electrode. A thickness of the thick-film resin body is larger than a thickness of the thin-film resin layer. A thermal expansion coefficient of the first film is between a thermal expansion coefficient of the thick-film resin body and a thermal expansion coefficient of the semiconductor. A thermal expansion coefficient of the second film is smaller than the thermal expansion coefficient of the thick-film resin body.

A method of manufacturing a semiconductor device according to a second aspect of the disclosure includes steps below. A base substrate is prepared. The base substrate includes a first main surface, a second main surface on an opposite side of the first main surface, and an array of a plurality of sections each including a semiconductor element in the first main surface, and includes a semiconductor. A thin-film metal electrode is formed on the first main surface in each of the sections of the base substrate. A thin-film resin layer is formed on the first main surface in each of the sections of the base substrate. The thin-film resin layer includes a first opening on the thin-film metal electrode and covers an edge of the thin-film metal electrode. A structure body that includes at least one of a first film and a second film is formed. The first film is formed on the thin-film resin layer of the first main surface of the base substrate, and the second film is formed on the second main surface of the base substrate. A metal thick film that includes a metal film containing copper is formed on the first main surface in each of the sections of the base substrate. The metal thick film is located above the thin-film metal electrode and is connected to the thin-film metal electrode via the first opening of the thin-film resin layer. A resin thick film is formed on the first main surface of each of the sections of the base substrate. The resin thick film covers an upper surface and a lateral surface of the metal thick film. The resin thick film and the metal thick film are ground after forming the structure body to form a thick-film resin body and a thick-film metal body respectively from the resin thick film and the metal thick film. The thick-film metal body, the thin-film metal electrode, and the base substrate are arranged along a direction of a first axis. An upper surface of the thick-film metal body and an upper surface of the thick-film resin body extend along a reference plane intersecting with the first axis. A thickness of the thick-film metal body is larger than a thickness of the thin-film metal electrode. A thickness of the thick-film resin body is larger than a thickness of the thin-film resin layer. A thermal expansion coefficient of the first film is between a thermal expansion coefficient of the thick-film resin body and a thermal expansion coefficient of the semiconductor. A thermal expansion coefficient of the second film is smaller than the thermal expansion coefficient of the thick-film resin body.

### BRIEF DESCRIPTION OF DRAWINGS

FIG. 1 is a plan view schematically showing a semiconductor device according to this embodiment.

FIG. 2 is a view showing the semiconductor device according to this embodiment in a cross section taken along line II-II shown in FIG. 1.

FIG. 3 is a view showing the semiconductor device according to this embodiment in a cross section taken along line III-III shown in FIG. 1.

FIG. 4 is a cross-sectional view showing a step in a method of manufacturing a semiconductor device according to this embodiment.

FIG. 5 is a cross-sectional view showing a step in the method of manufacturing a semiconductor device according to this embodiment.

FIG. 6 is a cross-sectional view showing a step in the method of manufacturing a semiconductor device according to this embodiment.

FIG. 7 is a cross-sectional view showing a step in the method of manufacturing a semiconductor device according to this embodiment.

FIG. 8 is a cross-sectional view showing a step in the method of manufacturing a semiconductor device according to this embodiment.

FIG. 9 is a cross-sectional view showing a step in the method of manufacturing a semiconductor device according to this embodiment.

FIG. 10 is a cross-sectional view showing a step in the method of manufacturing a semiconductor device according to this embodiment.

FIG. 11 is a cross-sectional view showing a step in the method of manufacturing a semiconductor device according to this embodiment.

FIG. 12 is a view showing main steps in the method of manufacturing a semiconductor device according to this embodiment.

### DESCRIPTION OF EMBODIMENTS

Embodiments of the disclosure provide a semiconductor device having a CSP structure capable of reducing warpage, and a method of manufacturing the semiconductor device.

Hereinafter, embodiments for carrying out the disclosure will be described with reference to the drawings.

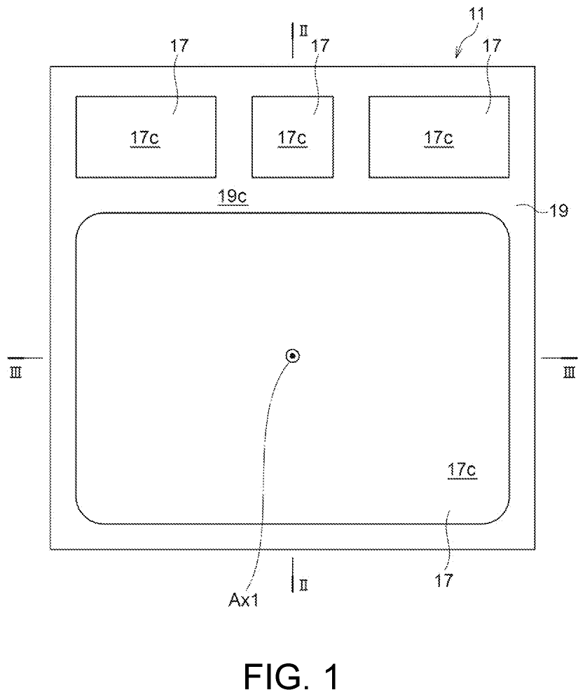

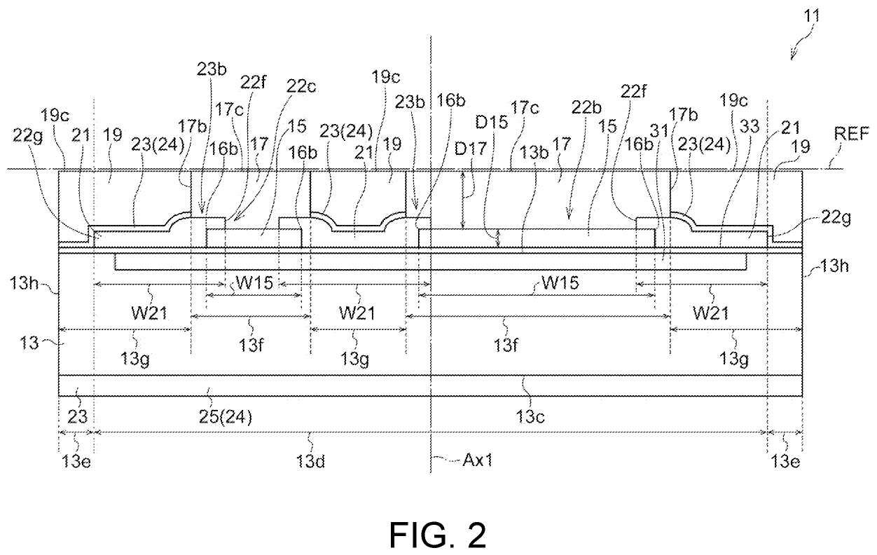

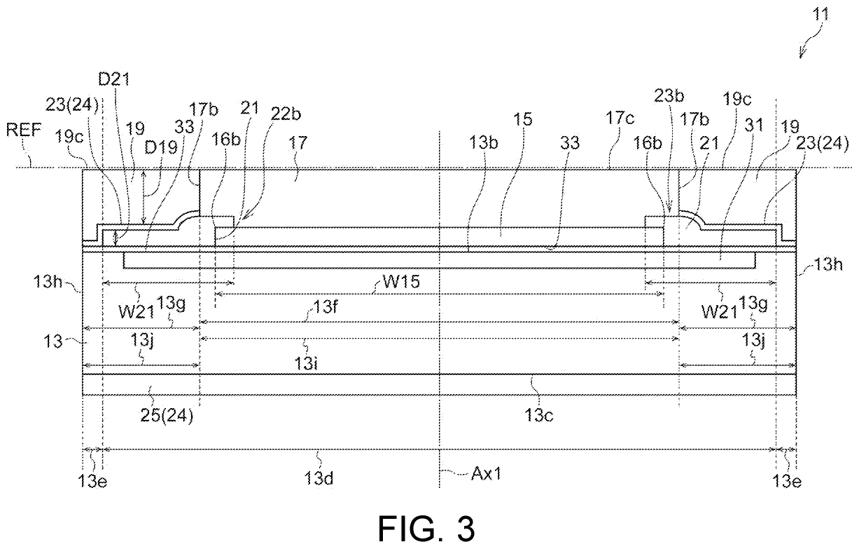

FIG. 1 is a plan view schematically showing a semiconductor device according to this embodiment. FIG. 2 is a view showing the semiconductor device according to this embodiment in a cross section taken along line II-II shown in FIG. 1. FIG. 3 is a view showing the semiconductor device according to this embodiment in a cross section taken along line III-III shown in FIG. 1. Hatching in the cross sections in FIG. 2 and FIG. 3 is omitted.

Referring to FIG. 1, FIG. 2, and FIG. 3, a semiconductor device 11 has a chip size package (or chip scale package, CSP) structure. Specifically, the semiconductor device 11 includes a support base 13 having a semiconductor (e.g., Group VI semiconductor such as silicon), at least one thin-film metal electrode 15, at least one thick-film metal body 17, a thick-film resin body 19, a thin-film resin layer 21, and a structure body 24 including at least one of a first film 23 and a second film 25.

The semiconductor device 11 may include one or more semiconductor elements 31 (e.g., active elements such as transistors) provided in the support base 13. Further, the semiconductor device 11 may include an insulating structure 33 provided between the thin-film metal electrode 15 and the semiconductor element 31. At least one semiconductor element 31 may be electrically connected to at least one thick-film metal body 17 via an opening of the insulating structure 33. The insulating structure 33 may include, for example, one or more insulating films, and the insulating film may include a silicon-based inorganic insulating film or a resin film.

The support base 13 has a first main surface 13b and a second main surface 13c on the opposite side of the first main surface 13b. The first main surface 13b has an element area 13d and a peripheral area 13e. The element area 13d includes the semiconductor element 31, and is mounted with the thick-film resin body 19, the thin-film metal electrode 15, and the thick-film metal body 17. The peripheral area 13e is mounted with the thick-film resin body 19. The thin-film metal electrode 15 and the thick-film metal body 17 are away from the peripheral area 13e. The peripheral area 13e surrounds the element area 13d. In this embodiment, an exemplary boundary between the peripheral area 13e and the element area 13d is set at an outer edge of the thin-film resin layer 21. However, the position of the boundary is not limited to this example.

The thin-film metal electrode 15 is provided on the first main surface 13b of the support base 13, and specifically, may be electrically connected to at least one semiconductor element 31. The thin-film metal electrode 15 may include, for example, aluminum.

The thick-film metal body 17 is located above the thin-film metal electrode 15 and the thin-film resin layer 21. The thick-film metal body 17 may include a metal film containing copper. The thick-film metal body 17 may include, for example, a copper plating film and a seed layer for plating.

The thick-film resin body 19 is provided on the first main surface 13b of the support base 13 and covers a lateral surface 17b of the thick-film metal body 17. The thick-film resin body 19 may include an epoxy resin.

The thin-film resin layer 21 has one or more first openings 22b and 22c, and each of the first openings (22b and 22c) is located above the thin-film metal electrode 15. In an embodiment, an edge 16b of the thin-film metal electrode 15 may be covered, and the thin-film resin layer 21 prevents the thick-film metal body 17 from reaching an underlying structure of the thin-film metal electrode 15 in the element area 13d. The thin-film resin layer 21 may include a polyimide resin.

The support base 13, the thin-film metal electrode 15, and the thick-film metal body 17 are arranged along a direction of a first axis Ax1. An upper surface 17c of the thick-film metal body 17 and an upper surface 19c of the thick-film resin body 19 may extend along a reference plane REF intersecting with the first axis Ax1, and there is substantially no level difference between the upper surface 17c of the thick-film metal body 17 and the upper surface 19c of the thick-film resin body 19.

The first film 23 of the structure body 24 may be provided on at least a portion of the first main surface 13b of the support base 13, and the second film 25 of the structure body 24 may be provided on at least a portion of the second main surface 13c of the support base 13. The first film 23 is one connected region, in which a total area of second openings 23b of the first film 23 is larger than a total area of an upper surface of the first film 23. In this embodiment, the first film 23 may extend outward beyond the boundary between the peripheral area 13e and the element area 13d and reach the edge of the first main surface 13b of the support base 13. Further, the second film 25 may extend outward beyond the boundary between the element area 13d and the peripheral area 13e on the second main surface 13c and reach the edge of the second main surface 13c of the support base 13.

The structure body 24 may include one or both of the first film 23 and the second film 25. In an exemplary structure body 24, the first film 23 may be provided between the thick-film resin body 19 and the thin-film resin layer 21, and the support base 13 may be provided between the thick-film resin body 19 and the second film 25.

The first film 23 separates the thick-film resin body 19 from the support base 13 and the thin-film resin layer 21 in the element area 13d. The second film 25 extends along the second main surface 13c of the support base 13. In this embodiment, the second film 25 is provided over the entire second main surface 13c, but this embodiment is not limited to this arrangement, and the second film 25 may also be provided on a main portion of the second main surface 13c.

A thickness D17 of the thick-film metal body 17 is larger than a thickness D15 of the thin-film metal electrode 15, and a thickness D19 of the thick-film resin body 19 is larger than a thickness D21 of the thin-film resin layer 21.

In this embodiment, the first film 23 may have a thermal expansion coefficient between a thermal expansion coefficient of the thick-film resin body 19 and a thermal expansion coefficient of the semiconductor of the support base 13. The second film 25 may have a thermal expansion coefficient smaller than the thermal expansion coefficient of the thick-film resin body 19.

According to the semiconductor device 11, the thickness D17 of the thick-film metal body 17 is larger than the thickness D15 of the thin-film metal electrode 15, and the thickness D19 of the thick-film resin body 19 is larger than the thickness D21 of the thin-film resin layer 21. This semiconductor device 11 can provide a structure (e.g., a CSP structure) for a chip size package, in which the upper surface 17c of the thick-film metal body 17 and the upper surface 19c of the thick-film resin body 19 extend along the reference plane REF. In this structure, the structure body 24 including at least one of the first film 23 and the second film 25 can reduce warpage of the support base 13 resulting from the stress from the thick-film metal body 17 and the thick-film resin body 19.

Further, since the thermal expansion coefficient of the first film 23 is between the thermal expansion coefficient of the thick-film resin body 19 and the thermal expansion coefficient of the semiconductor of the support base 13, it is possible to reduce the tensile stress from the thick-film metal body 17 and the thick-film resin body 19 to the support base 13.

Furthermore, by providing the second film 25 with a thermal expansion coefficient smaller than the thermal expansion coefficient of the thick-film resin body 19, it is possible to bring the thermal expansion coefficient of the second film 25 close to the thermal expansion coefficient of the support base 13 based on the thermal expansion coefficient of the thick-film resin body 19. Thus, the second film 25 acts to reduce warpage of the support base 13.

The first film 23 may include an inorganic insulator containing silicon and nitrogen, e.g., SiN. Further, the second film 25 may include an inorganic insulator containing silicon and nitrogen, e.g., SiN.

These films (23 and 25) may be formed on an underlying structure including a resin body at a film formation temperature not exceeding a heat resistance temperature of the underlying structure. The structure body 24 may include a silicon-based inorganic oxide film and/or a silicon-based inorganic oxynitride film capable of being deposited at a film formation temperature not exceeding the heat resistance temperature of the underlying structure.

In the structure body 24, specifically, the first film 23 has the second opening 23b, and the second opening 23b is located above the thin-film metal electrode 15 and the first openings 22b and 22c of the thin-film resin layer 21. The thick-film metal body 17 is connected to the thin-film metal electrode 15 via the second opening 23b of the first film 23, and in this embodiment, the thick-film metal body 17 is located above the thin-film metal electrode 15 and the thin-film resin layer 21. Between the support base 13 and the thick-film resin body 19, the first film 23 extends from the edge of the second opening 23b of the first film 23 toward an edge 13h of the support base 13.

According to this semiconductor device 11, the first film 23 is provided to extend along the support base 13 from the edge of the second opening 23b of the first film 23 toward the edge 13h of the support base 13 to surround a bottom part of the thick-film metal body 17 around its periphery. The first film 23 acts to maintain the coplanarity of the support base 13 between the support base 13 and the thick-film resin body 19.

In this embodiment, the second film 25 may extend from the edge or the vicinity of the edge of the second main surface 13c, e.g., from a position away from the edge, along the second main surface 13c, toward the center of the second main surface 13c.

According to this semiconductor device 11, the second film 25 extends along the second main surface 13c of the support base 13 and acts to maintain the coplanarity of the support base 13.

Referring to FIG. 1, four thick-film metal bodies 17 are provided, and the thick-film resin body 19 is provided between the thick-film metal bodies 17 to provide a CSP structure. In an exemplary semiconductor device 11, each of the thick-film metal bodies 17 is connected to the underlying thin-film metal electrode 15 via one first opening 22b and one second opening 23b. In an exemplary semiconductor device 11, a potential stress applied to the support base 13 by the thick-film metal body 17 is associated not only with an area of the upper surface 17c of the thick-film metal body 17 but also with a volume of the thick-film metal body 17. A proportion (hereinafter referred to as a “filling ratio”) that the thick-film metal body 17 occupies on the support base 13 may be defined, for example, in a wafer product in a wafer process or in a semiconductor chip.

According to estimations, conventional semiconductor chips have a filling ratio of 20 percent to 30 percent. A higher filling ratio may be estimated in the wafer product during the wafer process and in the semiconductor chip manufactured from the completed wafer product.

Referring to FIG. 1, FIG. 2, and FIG. 3, the thin-film metal electrode 15 may include one or more pad electrodes. The thick-film metal body 17 may include one or more metal pillars connected to the pad electrodes of the thin-film metal electrode 15. The first main surface 13b of the support base 13 includes a first area 13f and a second area 13g. The first area 13f is mounted with the metal pillars of the thick-film metal body 17, and the second area 13g is mounted with the thick-film resin body. In this embodiment, an area of the first area 13f is larger than an area of the second area 13g.

According to this semiconductor device 11, since the area of the first area 13f is larger than the area of the second area 13g, the semiconductor device 11 has a structure in which the support base 13 receives a stress from the thick-film metal body 17 in the first area 13f. The thick-film resin body 19 is provided to cover the lateral surface 17b of the thick-film metal body 17 in the second area 13g of the support base 13. In this structure, the support base 13 receives a stress from the thick-film resin body 19 in the second area 13g.

Further, as shown in FIG. 3, the second main surface 13c includes a third area 13i and a fourth area 13j. The third area 13i and the fourth area 13j are defined to respectively correspond to the first area 13f and the second area 13g of the first main surface 13b and correspondingly associated with the second main surface 13c.

The second film 25 may be provided at least on the third area 13i and supports the support base 13 against the thick-film metal body 17. The second film 25 may extend (on the fourth area 13j) outward beyond a boundary between the third area 13i and the fourth area 13j, and supports the support base 13 against the thick-film metal body 17 and the thick-film resin body 19. The second film 25 may be away from the edge 13h of the support base 13.

Although not depicted in FIG. 1, referring to FIG. 2 and FIG. 3, the thin-film metal electrode 15 is located directly below the thick-film metal body 17. The first openings 22b and 22c of the thin-film resin layer 21 are located above the thin-film metal electrode 15. The thick-film metal body 17 covers the entire upper surface of the thin-film metal electrode 15 in the first openings 22b and 22c of the thin-film resin layer 21, and extends on the upper surface of the thin-film resin layer 21 beyond the edge of the thin-film resin layer 21.

An area (size W15) of the upper surface of the thin-film metal electrode 15 is larger than an area (size W21) of the upper surface of the thin-film resin layer 21.

According to this semiconductor device 11, the thick-film metal body 17 is bonded to the thin-film metal electrode 15 provided on the first main surface 13b of the support base 13 via the first openings 22b and 22c of the thin-film resin layer 21. The thin-film resin layer 21 is provided on the first main surface 13b of the support base 13 avoiding the bonding between the thin-film metal electrode 15 and the thick-film metal body 17, and provides a planarized surface on the first main surface 13b of the support base 13. The planarized surface is provided to a base of the first film 23 to avoid potential increases in a thermal stress resulting from bending or a step in a base of the thick-film resin body 19 and/or the thick-film metal body 17.

Referring to FIG. 1, FIG. 2, and FIG. 3, the thick-film metal body 17 covers the entire upper surface of the thin-film metal electrode 15 in the first openings 22b and 22c of the thin-film resin layer 21. Further, the thin-film resin layer 21 is one connected region, in which a total area of the first openings 22b and 22c of the thin-film resin layer 21 is larger than a total area of the upper surface of the thin-film resin layer 21.

According to this semiconductor device 11, the thin-film resin layer 21 is provided on the first main surface 13b of the support base 13 avoiding the bonding between the thick-film metal body 17 and the thin-film metal electrode 15, and the total area of the first openings 22b and 22c of the thin-film resin layer 21 becomes larger than the total area of the upper surface of the thin-film resin layer 21. With the thin-film resin layer 21 formed as one connected region, the thin-film resin layer 21 can be provided to cover on more of the first main surface 13b of the support base 13. A planarized base can be provided for the first film 23.

Similarly, the thick-film resin body 19 is also provided on the first main surface 13b of the support base 13 avoiding the bonding between the thick-film metal body 17 and the thin-film metal electrode 15. The thick-film resin body 19 is one connected region, in which a total area of openings of the thick-film resin body 19 is larger than a total area of the upper surface of the thick-film resin body 19.

Referring to FIG. 2, the thin-film resin layer 21 has an inner edge 22f that defines the first openings 22b and 22c of the thin-film resin layer 21, and an outer edge 22g that defines the size of the thin-film resin layer 21. The outer edge 22g of the thin-film resin layer 21 is away from the edge 13h of the support base 13, and the thick-film resin body 19 reaches the edge 13h of the support base 13.

According to this semiconductor device 11, the thin-film resin layer 21 can be provided up to the vicinity of the edge 13h of the support base 13, e.g., up to the edge of a scribe area of the support base 13.

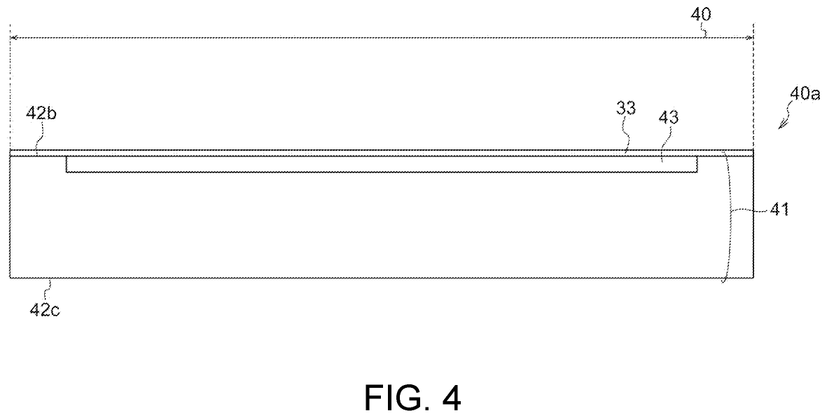

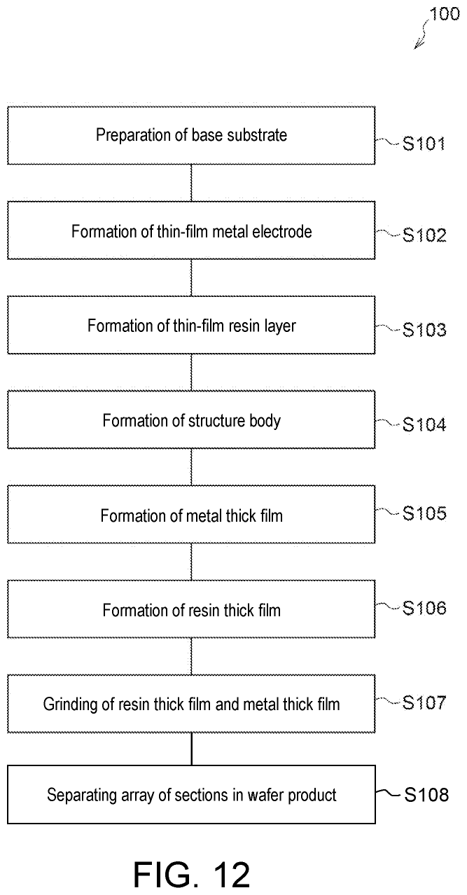

FIG. 4 to FIG. 11 are cross-sectional views showing main steps in a method of manufacturing the semiconductor device according to this embodiment. Each of FIG. 4 to FIG. 11 shows a progress of a wafer product during manufacturing in a cross section corresponding to line III-III shown in FIG. 1. Hatching in each cross section in FIG. 4 to FIG. 11 is omitted. FIG. 12 is a flowchart showing main steps in the method of manufacturing the semiconductor device according to the embodiment. In the following description, to facilitate understanding, wherever possible, identical or similar portions will be labeled with reference signs already used in the above description.

In a first step (e.g., S101 in FIG. 12) shown in FIG. 4, a base substrate 41 processed from, for example, a semiconductor wafer is prepared. The base substrate 41 may include a semiconductor such as silicon. A semiconductor region of the base substrate 41 has a first main surface 42b and a second main surface 42c on the opposite side of the first main surface 42b. The base substrate 41 has an arrangement (e.g., a one-dimensional or two-dimensional array) of a plurality of sections (40 in FIG. 4) on the first main surface 42b. Each of the sections 40 includes a semiconductor element 43. FIG. 4 to FIG. 11 depict one section. The semiconductor element 43 is formed in the region of semiconductor. The semiconductor element 43 may include elements such as a transistor, an electrode, and an interconnecting wiring, and these elements may be created by applying a plurality of semiconductor processes to a semiconductor substrate such as a wafer.

In a second step, the base substrate 41 is covered with an insulating structure 33 to obtain a wafer product 40a. The insulating structure 33 may include at least one of an inorganic insulator and an organic insulator, and specifically, the insulating structure 33 covers the region of the semiconductor element 43.

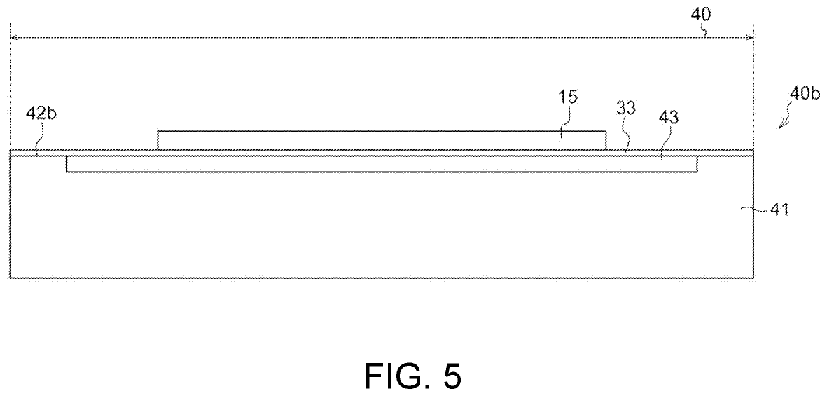

In a third step (e.g., S102 in FIG. 12) shown in FIG. 5, a thin-film metal electrode 15 is formed in each of the sections 40 to obtain a wafer product 40b. The thin-film metal electrode 15 is formed on the first main surface 42b of the base substrate 41 (specifically, on the insulating structure 33), and may be connected to the semiconductor element 43 in the section 40 via an opening of the insulating structure 33. For example, semiconductor processes such as deposition of a metal layer, photolithography, and etching are used in the formation of the thin-film metal electrode 15. The thin-film metal electrode 15 may include, for example, aluminum.

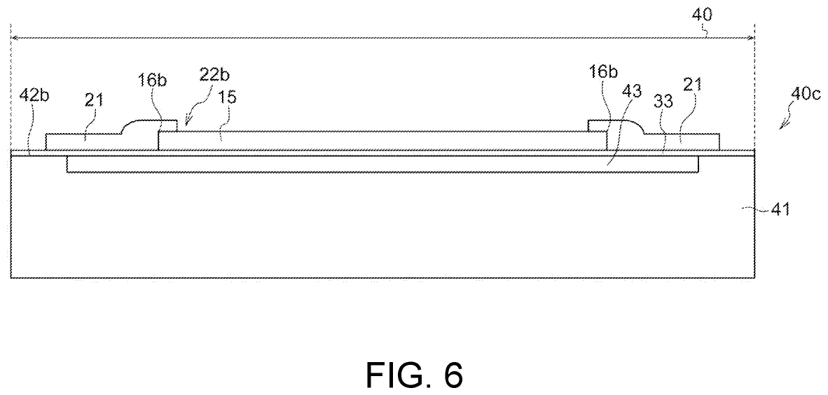

In a fourth step (e.g., S103 in FIG. 12) shown in FIG. 6, a thin-film resin layer 21 is formed on the first main surface 42b in each of the sections 40 to obtain a wafer product 40c. The thin-film resin layer 21 has a first opening 22b on the thin-film metal electrode 15 and covers an edge 16b of the thin-film metal electrode 15. For example, semiconductor processes such as coating of an organic substance, baking, photolithography, and etching are used in the formation of the thin-film resin layer 21. The thin-film resin layer 21 may include, for example, a polyimide resin.

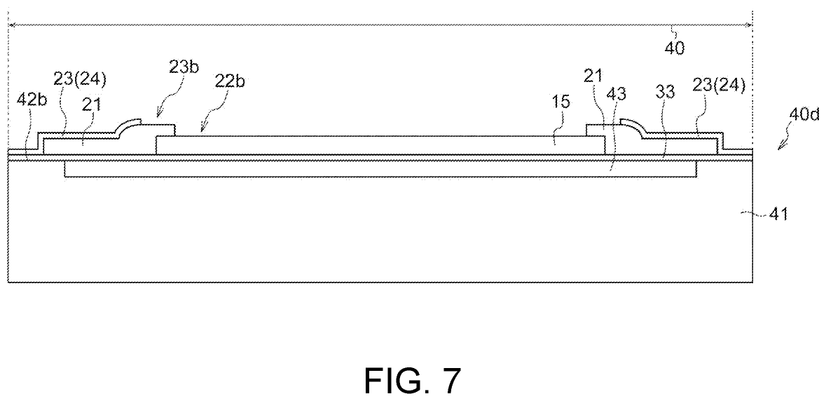

In a fifth step (e.g., S104 in FIG. 12) shown in FIG. 7, a structure body 24 is formed. In this step, as an example of the structure body 24, a first film 23 is formed to obtain a wafer product 40d. The first film 23 is formed on the thin-film resin layer 21 on the first main surface 42b of the base substrate 41. The first film 23 has a second opening 23b on the thin-film metal electrode 15, and the second opening 23b is aligned with the first opening 22b. In this embodiment, the size of the second opening 23b is larger than the size of the first opening 22b. The first film 23 may include, for example, a silicon-based inorganic nitride such as SiN.

Another example of the structure body 24, specifically formation of a second film 25, will be described later.

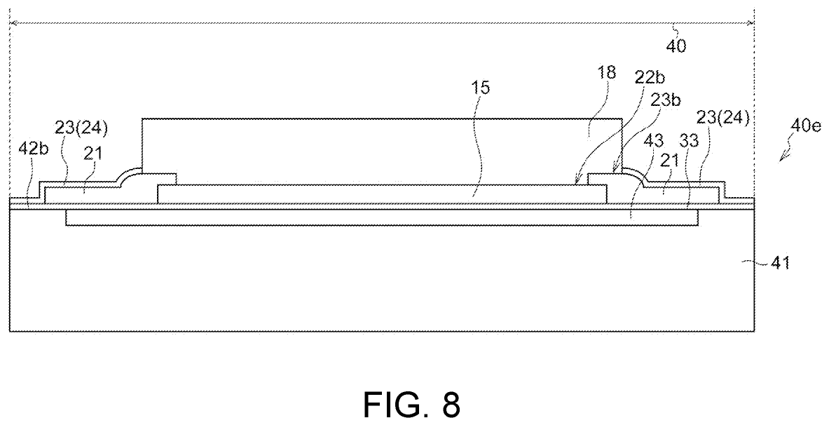

In a sixth step (e.g., S105 in FIG. 12) shown in FIG. 8, a metal thick film 18 is formed on the first main surface 42b in each of the sections 40 to obtain a wafer product 40e. The metal thick film 18 may include copper. The metal thick film 18 is located above the thin-film metal electrode 15 and is connected to the thin-film metal electrode 15 via the first opening 22b of the thin-film resin layer 21. The metal thick film 18 has a thickness larger than a thickness of the thick-film metal body 17. In the formation of the metal thick film 18, for example, a plating method is used, specifically, semiconductor processes such as deposition of a seed layer (pattern formation, wherever necessary), formation of an electrolytic plating film, and removal of the seed layer (wherever necessary) are used.

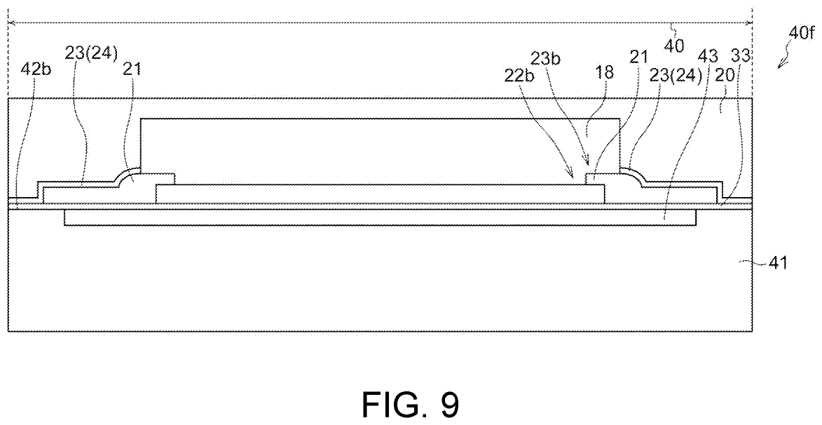

In a seventh step (e.g., S106 in FIG. 12) shown in FIG. 9, a resin thick film 20 is formed on the first main surface 42b in each of the sections 40 to obtain a wafer product 40f. The resin thick film 20 is formed to cover the upper surface and the lateral surfaces of the metal thick film 18. The resin thick film 20 has a thickness larger than a thickness of the thick-film resin body 19. Further, the resin thick film 20 has a thickness larger than the thickness of the metal thick film 18. In the formation of the resin thick film 20, for example, coating is used, and specifically, semiconductor processes such as coating of an organic substance and baking are used. The resin thick film 20 may include, for example, an epoxy resin.

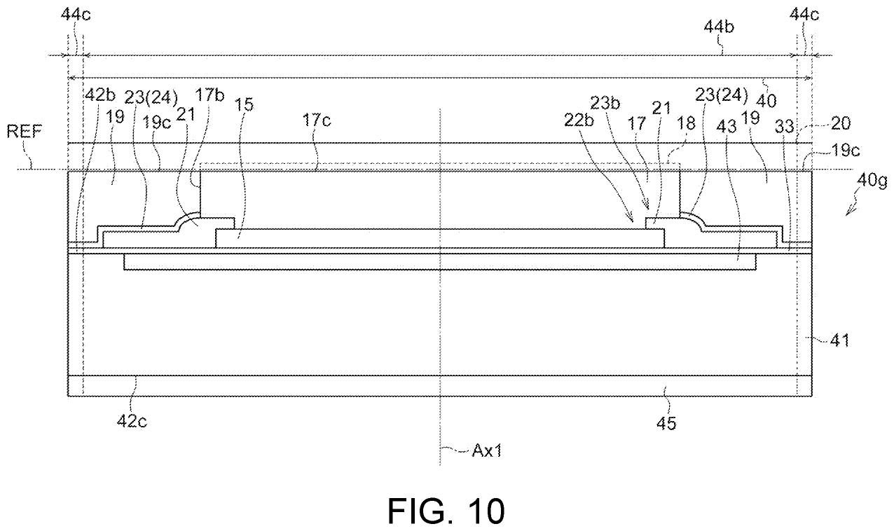

In an eighth step (e.g., S107 in FIG. 12) shown in FIG. 10, the resin thick film 20 and the metal thick film 18 are ground to form a thick-film resin body 19 and a thick-film metal body 17 respectively from the resin thick film 20 and the metal thick film 18 to obtain a wafer product 40g. Before grinding, the wafer product 40e is fixed to a support plate 45. Specifically, the support plate 45 is adhered to the second main surface 42c, and is separated from the wafer product 40g after grinding.

In the wafer product 40g, in each of the sections 40, a lateral surface 17b of the thick-film metal body 17 is covered by the thick-film resin body 19, and the thick-film metal body 17 is accommodated in the opening of the thick-film resin body 19.

The base substrate 41, the thin-film metal electrode 15, and the thick-film metal body 17 are arranged along a direction of a first axis Ax1. An upper surface 17c of the thick-film metal body 17 and an upper surface 19c of the thick-film resin body 19 may extend along a reference plane REF intersecting with the first axis Ax1, and there is substantially no level difference between the upper surface 17c of the thick-film metal body 17 and the upper surface 19c of the thick-film resin body 19.

According to this manufacturing method, a thickness of the thick-film metal body 17 is larger than the thickness of the thin-film metal electrode 15, and a thickness of the thick-film resin body 19 is larger than the thickness of the thin-film resin layer 21. This semiconductor device 11 can provide a structure for a chip size package, in which the upper surface 17c of the thick-film metal body 17 and the upper surface 19c of the thick-film resin body 19 extend along the reference plane REF. In this structure, the structure body 24 (including the first film 23) can reduce warpage of the base substrate 41 resulting from the stress from the thick-film metal body 17 and the thick-film resin body 19 in each of the sections 40.

In the above manufacturing method, the formation of the structure body 24 has been described in the fifth step. However, the structure body 24 may be formed after forming the thin-film resin layer 21 and before forming the thick-film resin body 19. Specifically, the first film 23 of the structure body 24 may be formed after forming the thick-film metal body 17, and the first film 23 may cover the surface of the thin-film resin layer 21 and the lateral surface and the upper surface of the metal thick film 18.

Wherever necessary, the manufacturing method of the semiconductor device 11 may include a ninth step of forming another exemplary structure body 24. In the ninth step, a second film 25 provided on at least a portion of the second main surface 42b is formed to thus provide a wafer product. The second film 25 may include, for example, a silicon-based inorganic nitride such as SiN.

The ninth step may be, for example, after any of the first step to the fourth step, and before the sixth step or the seventh step.

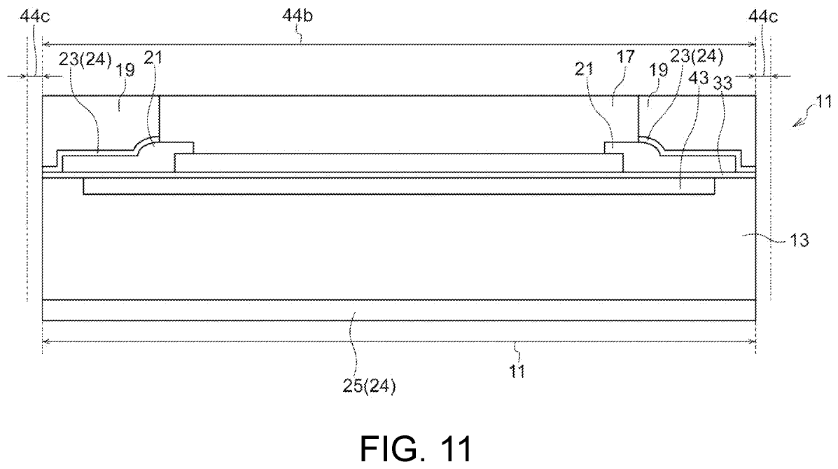

In a tenth step (e.g., S108 in FIG. 12) shown in FIG. 11, an array of sections 40 in the wafer product 40g is separated to obtain a plurality of semiconductor devices 11. Each of the semiconductor devices 11 has a form of a semiconductor chip.

According to the above manufacturing method, the semiconductor device 11 and the wafer product 40g are provided.

Next, another formation method of the structure body 24 will be described. The manufacturing method may include at least the first step to the fourth step and the sixth step to the ninth step.

Next, still another formation method of the structure body 24 will be described. This manufacturing method may include at least the first step to the tenth step. The semiconductor device 11 manufactured from this manufacturing method is provided with a structure body 24 that includes both the first film 23 and the second film 25.

Referring to FIG. 10 and FIG. 11 again, it is understood that each of the sections 40 includes an element area 44b and a half of a separation area 44c. The wafer product 40g (and the base substrate 41) includes a two-dimensional array of sections 40.

The wafer product 40g (and the base substrate 41) includes a grid array (two-dimensional array) of element areas 44b and a separation area 44c in a grid pattern defining the array of the element areas 44b. The separation area 44c extends between any one element area 44b in the grid array and element areas 44b adjacent to this element area 44b.

According to the manufacturing method, it is possible to reduce warpage of the base substrate 41 without reducing the shot rate in photolithography.

The wafer product 40g includes the base substrate 41, and includes the element areas 44b in the sections 40 arranged in a grid, and the separation area 44c in a grid pattern extending along the boundaries of these sections 40. The wafer product 40g further includes, in each section or at least one section, at least one thin-film metal electrode 15 provided on the first main surface 42b, and at least one thick-film metal body 17 provided on the first main surface 42b. Further, the wafer product 40g includes the thick-film resin body 19 provided on the first main surface 42b across the sections 40 and filling between the thick-film metal bodies 17. Furthermore, the wafer product 40g further includes the structure body 24 provided on at least one of the first main surface 42b and the second main surface 42c of the base substrate 41. The structure body 24 includes at least one of the first film 23 and the second film 25.

The wafer product 40g is provided with the above configurations, and as already described, the wafer product 40g has a large filling ratio.

Referring to FIG. 12 again, a method 100 of manufacturing a semiconductor device 11 that includes creation methods of several exemplary structure bodies includes the fifth step (step S105) and/or the ninth step. The method 100 may further include at least one of step S101 to step S104 and step S106 to step S108. Next, each of the steps will be described. In step S101, a base substrate 41 is prepared. In step S102, a thin-film metal electrode 15 is formed. In step S103, a thin-film resin layer 21 is formed. In step S104, a structure body 24 including at least one of a first film 23 and a second film 25 is formed. In step S105, a metal thick film 18 is formed. In step S106, a resin thick film 20 is formed. In step S107, the metal thick film 18 and the resin thick film 20 are ground to form a thick-film metal body 17 and a thick-film resin body 19 respectively from the metal thick film 18 and the resin thick film 20. In step S108, an array of sections 40 in the wafer product 40g is separated to obtain a plurality of semiconductor devices 11. According to the above method 100, the semiconductor device 11 and the wafer product 40g are provided.

According to this embodiment, a semiconductor device 11 having a CSP structure capable of reducing warpage, and a method 100 of manufacturing the semiconductor device are provided.

The disclosure is not limited to the embodiments described above, and various modifications may be made without departing from the spirit of the disclosure. All of such modifications are included in the technical concept of the disclosure.

What is claimed is:

1. A semiconductor device comprising:
a support base that comprises a first main surface and a second main surface on an opposite side of the first main surface, and comprises a semiconductor;
at least one thin-film metal electrode that is provided on the first main surface of the support base;
a thin-film resin layer that comprises a first opening on the thin-film metal electrode and covers an edge of the thin-film metal electrode;
at least one thick-film metal body that is located above the thin-film metal electrode and the thin-film resin layer and comprises a metal film containing copper;
a thick-film resin body that covers a lateral surface of the thick-film metal body and is provided on the first main surface of the support base; and
a structure body that comprises at least one of a first film provided on at least a portion of the first main surface of the support base and a second film provided on at least a portion of the second main surface of the support base, wherein the first film is provided between the thin-film resin layer and the thick-film resin body, and the support base is provided between the second film and the thick-film resin body, wherein
the thick-film metal body, the thin-film metal electrode, and the support base are arranged along a direction of a first axis,
an upper surface of the thick-film metal body and an upper surface of the thick-film resin body extend along a reference plane intersecting with the first axis,
a thickness of the thick-film metal body is larger than a thickness of the thin-film metal electrode,
a thickness of the thick-film resin body is larger than a thickness of the thin-film resin layer,
a thermal expansion coefficient of the first film is between a thermal expansion coefficient of the thick-film resin body and a thermal expansion coefficient of the semiconductor, and
a thermal expansion coefficient of the second film is smaller than the thermal expansion coefficient of the thick-film resin body.

2. The semiconductor device according to claim 1, wherein
the thin-film metal electrode comprises one or more pad electrodes,
the thick-film metal body comprises one or more metal pillars connected to the pad electrodes,
the first main surface of the support base comprises a first area mounted with the metal pillar and a second area mounted with the thick-film resin body, and
an area of the first area is larger than an area of the second area.

3. The semiconductor device according to claim 1, wherein
the thick-film metal body covers an entirety of an upper surface of the thin-film metal electrode in the first opening of the thin-film resin layer, and
an area of the upper surface of the thin-film metal electrode is larger than an area of an upper surface of the thin-film resin layer.

4. The semiconductor device according to claim 1, wherein
the thin-film resin layer is one connected region, in which a total area of the first opening of the thin-film resin layer is larger than a total area of an upper surface of the thin-film resin layer.

5. The semiconductor device according to claim 1, wherein
the first film comprises an inorganic insulator containing silicon and nitrogen.

6. The semiconductor device according to claim 1, wherein
the second film comprises an inorganic insulator containing silicon and nitrogen.

7. A method of manufacturing a semiconductor device, comprising:
preparing a base substrate that comprises a first main surface, a second main surface on an opposite side of the first main surface, and an array of a plurality of sections each comprising a semiconductor element in the first main surface, and comprises a semiconductor;
forming a thin-film metal electrode on the first main surface in each of the sections of the base substrate;
forming a thin-film resin layer on the first main surface in each of the sections of the base substrate, wherein the thin-film resin layer comprises a first opening on the thin-film metal electrode and covers an edge of the thin-film metal electrode;
forming a structure body that comprises at least one of a first film and a second film, wherein the first film is formed on the thin-film resin layer of the first main surface of the base substrate, and the second film is formed on the second main surface of the base substrate;
forming a metal thick film that comprises a metal film containing copper on the first main surface in each of the sections of the base substrate, wherein the metal thick film is located above the thin-film metal electrode and is connected to the thin-film metal electrode via the first opening of the thin-film resin layer;
forming a resin thick film on the first main surface of each of the sections of the base substrate, wherein the resin thick film covers an upper surface and a lateral surface of the metal thick film; and
grinding the resin thick film and the metal thick film after forming the structure body to form a thick-film resin body and a thick-film metal body respectively from the resin thick film and the metal thick film, wherein
the thick-film metal body, the thin-film metal electrode, and the base substrate are arranged along a direction of a first axis,
an upper surface of the thick-film metal body and an upper surface of the thick-film resin body extend along a reference plane intersecting with the first axis,
a thickness of the thick-film metal body is larger than a thickness of the thin-film metal electrode,
a thickness of the thick-film resin body is larger than a thickness of the thin-film resin layer,
a thermal expansion coefficient of the first film is between a thermal expansion coefficient of the thick-film resin body and a thermal expansion coefficient of the semiconductor, and
a thermal expansion coefficient of the second film is smaller than the thermal expansion coefficient of the thick-film resin body.
